(19) United States
(12) Patent Application Publication
(10) Pub. No.: US 2011/0141710 A1
(43) Pub. Date: Jun. 16, 2011

(54) Card Retention Apparatus

(76) Inventors: Trentent Tye, Calgary (CA); Troy Tye, St. Albert (CA); Mark C. Solomon, San Jose, CA (US)

(21) Appl. No.: 12/812,750

(22) PCT Filed: Jan. 24, 2008
(86) PCT No.: PCT/US2008/051895

§ 371 Date: Mar. 2, 2011

(51) Int. Cl. H05K 5/00

(52) U.S. Cl. 361/759

(57) ABSTRACT

An apparatus comprises a rail and a securing member. The securing member is slidably coupled to the rail. The securing member is adapted to secure a card in a socket by contacting an edge of the card.

### BACKGROUND

Some cards in computer systems, e.g. high-end gaming systems, are long and contain heavy cooling elements. In a computer chassis, the weight of the cooling elements unfortunately contributes to shaking the card out of its socket during shipping or even causes the cards to flex or bend. As such, card retention mechanisms are employed to keep the card in place. However, cards and cooling solutions are not static. The dimensions of cards change over time, and the cooling solutions on, e.g., video cards may change with each revision of the card, whereas the computer chassis remains the same. For example, some cooling solutions physically extend beyond the card. Such cooling solutions cannot be used if a card retention mechanism blocks the space beyond the card, but elimination of the card retention mechanism would eliminate the stability provided by the card retention mechanism. Computer manufacturers who ship computer systems with bulky, heavy cooling solutions are especially vulnerable to these problems.

### BRIEF DESCRIPTION OF THE DRAWINGS

For a detailed description of exemplary embodiments of the invention, reference will now be made to the accompanying drawings in which:

FIGS. 1A-1D illustrate a securing member slidably coupled to a rail in a computer chassis in accordance with at least one exemplary embodiment.

FIG. 2A illustrates the rail in a perspective view in accordance with at least one exemplary embodiment;

FIG. 2B illustrates the rail in a side view in accordance with at least one exemplary embodiment;

FIG. 3A illustrates a securing member in accordance with at least one exemplary embodiment;

FIG. 3B illustrates an end of the securing member in an exploded view in accordance with at least one exemplary embodiment;

FIG. 4 illustrates the securing member fastened to a computer chassis in accordance with at least one exemplary embodiment; and

FIGS. 5A and 5B illustrate a securing member being repositioned in accordance with at least one exemplary embodiment.

### NOTATION AND NOMENCLATURE

Certain terms are used throughout the following description and claims to refer to particular system components. As one skilled in the art will appreciate, different companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .”

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

To overcome the aforementioned obstacles, an apparatus is disclosed. Preferably, the apparatus comprises a rail and a securing member. The rail is preferably coupled to a computer chassis, and the securing member is slidably coupled to the rail. The securing member holds a stacked arrangement of cards in place by contacting the edges of the cards in the computer chassis, but the securing member can be repositioned by sliding or rolling along the rail, thus contacting the cards in a different location. As such, should the securing member impede implementation of a cooling solution, the securing member can be repositioned along the rail such that the securing member contacts the cards in other locations where the securing member will not impede the cooling solution. Similarly, should a new card of different dimensions than the other cards be added to the stacked arrangement of cards, and should the original position of the securing member not allow for contact with the new card, the securing member can be repositioned along the rail such that all the cards in the stacked arrangement of card are contacted and secured.

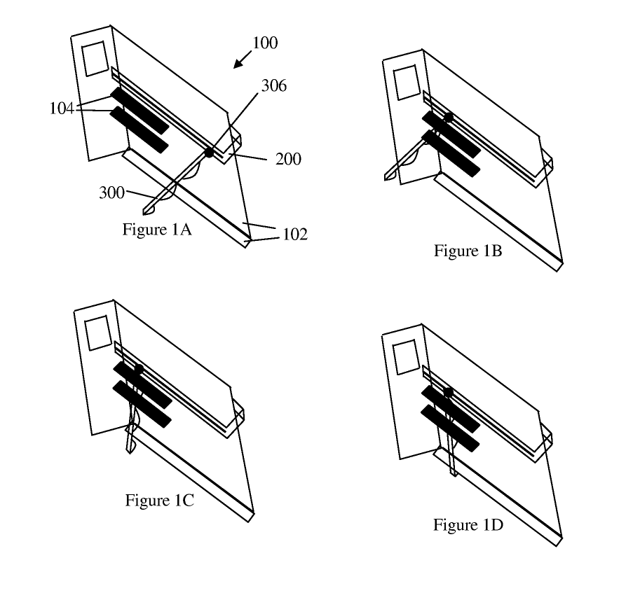

FIGS. 1A-1D illustrate a computer 100 comprising the rail 200 and the securing member 300. Also shown is a stacked arrangement of cards 104, each card in a socket. For clarity, the computer 100 is shown in a perspective view, with a portion of the chassis cut away, and without some components such as a monitor and motherboard. The rail 200 is coupled to the computer chassis 102, and the securing member 300 is slidably coupled to the rail, i.e., the securing member 300 slides or rolls along the rail 200. Taken together, the figures illustrate that the securing member 300 slides along the rail 200 towards the stacked arrangement of cards 104 and rotates about a hinge 306. Moving from FIG. 1A to FIG. 1B, the securing member 300 slides along the rail 200. Moving from FIG. 1B to FIG. 10 the securing member 300 rotates about the hinge 306. Moving from FIGS. 10 to 1D, the securing member 300 has completed rotation and is fastened to the computer chassis 102. When fastened to the computer chassis 102, the securing member 300 secures the stacked arrangement of cards 104 into their respective sockets.

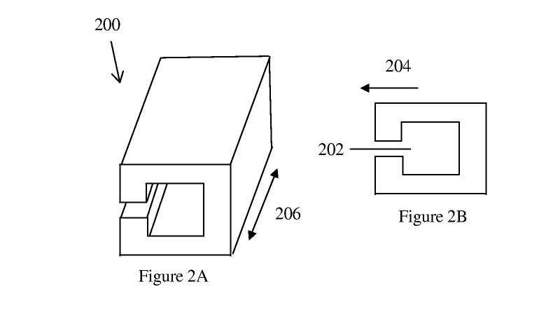

FIG. 2A illustrates a perspective view of the rail 200. FIG. 2B illustrates a side view of the rail 200. As one skilled in the art will appreciate, the rail 200 can be implemented in a myriad of designs. As pictured, the rail 200 comprises a “C” shaped member. Preferably, the rail 200 is made of metal or plastic material, though other materials are within the scope of this document. The rail 200 anchors the securing member 300 via a slideable coupling. Specifically, the rail 200 comprises a groove, or cavity, 202 in which a portion of the securing member 300 slides or rolls. In various embodiments, the slidable coupling is implemented with a low-friction surface or wheels to allow for motion of the securing member 300 along the rail 200. In at least one embodiment, the shape of the rail 200 forms the groove 202 and holds the securing member 300 within the groove 202. Preferably, the securing member 300 cannot exit the groove in the direction indicated by arrow 204, but can exit the groove 202, and hence decouple from the rail 200, by sliding along the rail 200 in the directions indicated by double arrow 206 until either the end of the rail 200 is reached. In at least one embodiment, one end of the rail 200 is sealed and the securing member 300 only couples and decouples from the rail 200 at the other end. In at least one embodiment, the rail 200 comprises a single member as pictured. In other embodiments, the rail 200 comprises multiple members coupled together to form the groove 202.

In at least one embodiment, the rail 200 and the groove 202 extend commensurate with the edge of the cards 104 that the securing member 300 secures. Because, the securing member 300 is slidably coupled to the rail 200, the securing member 300 is positioned and repositioned along the rail 200 to contact any point along the edges of the cards 104 as desired. Preferably, the edges that are contacted are the edges opposite the edge coupled to the card sockets.

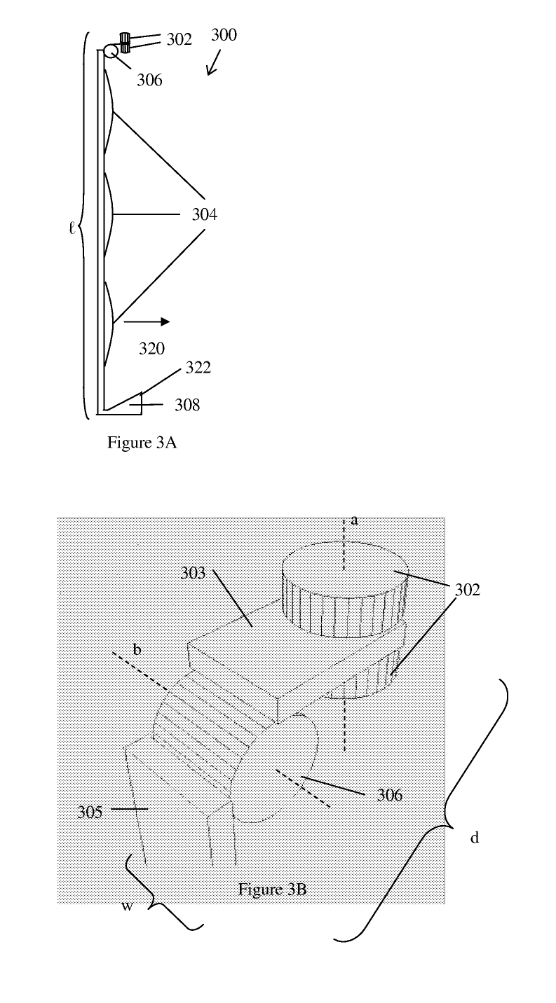

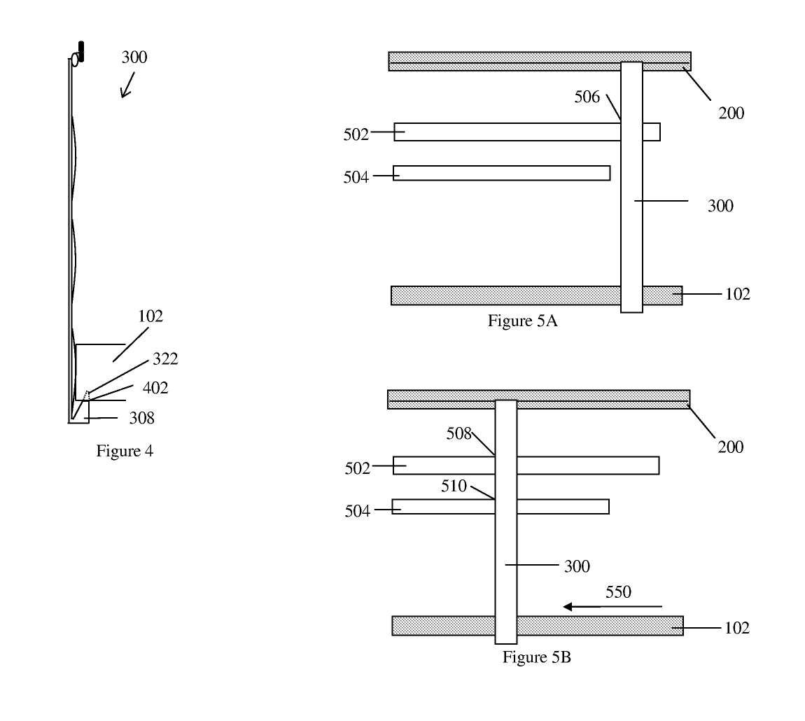

FIG. 3A illustrates the securing member 300, and FIG. 3B illustrates a section of the securing member 300 in an exploded view. FIG. 4 illustrates the securing member 300 fastened to the chassis 102. The securing member 300 preferably comprises a first portion 303, a second portion 305, and a hinge 306. The hinge 306 enables second portion 305 of the securing member 300 to rotate and reach the stacked arrangement of cards 104. The securing member 300 contacts the edges of the cards 104 to secure the cards 104. With the hinge 306 rotating about axis “b,” the second portion 305 of the securing member 300 can lie generally perpendicular to the horizontal plane of the rail 200 as well as the horizontal plane of each card 104 in the stacked arrangement of cards 104 in order to exert pressure or provide resistance and support to the edge of each card 104.

In at least one embodiment, at the point of contact, the securing member 300 preferably comprises an elastic or flexible portion 304, e.g. a spring, to reduce strain on the securing member 300 and provide a cushion to a card 104. As pictured, three elastic portions 304 are disposed evenly along the second portion 305 of the securing member 300. In at least one embodiment, any number of elastic portions secure any number of cards 104 in a one-to-one ratio. Preferably, when contact is made with a card 104, the elastic portion 304 is depressed such that the elastic portion 304 exerts pressure on the card in the direction indicated by the arrow 320. The amount of pressure is preferably sufficient to secure the card 104 in a socket, but not to damage the card 104, securing member 300, or socket.

In at least one embodiment, the slidable coupling between the securing member 300 and the rail 200 is implemented as the rail 200 comprising a track along which a portion of the securing member 300 rolls. Preferably, the securing member 300 comprises wheels 302 that roll within the groove 202 and allow for motion of the securing member 300 along the rail 200. The wheels 302 are disposed on either side of the first portion 303 of the securing member 300, and the wheels 302 turn about axis “a” allowing the securing member 300 to move along the rail 200. The wheels 302 are removably coupled to the rail 200. In order to decouple the wheels 302, and hence the entire securing member 300, from the rail 200, the securing member 300 is rolled towards an end of the rail 200. In at least one embodiment, the securing member 300 has a length (0, a width (w), and a depth (d) that is, for example, six inches, half of an inch, and half of an inch, respectively. The wheels 302 are small enough to fit within the groove 202, and are preferably made of a durable material ideal for repetitive rolling along the rail 200.

As mentioned, the securing member 300 is adapted to secure one or more cards 104 in respective sockets by contacting any point along the edges of the cards 104. In various embodiments, the cards 104 comprise any type of card such as a video card, a sound card, a peripheral component interconnect (“PCI”) card, a PCI Express card, a network card, a tuner card, an expansion card, an accelerated graphics port (“AGP”) card, an industry standard architecture (“ISA”) card, a micro-channel architecture (“MCA”) card, a video electronics standards association (“VESA”) card, a physics card, a power-on self test (“POST”) card, a modem card, a host adapter card, an interface adapter card, a disk controller card, a memory card, a flash card, a computer add-in card, or a modem card. If multiple cards 104 are secured in place by the securing member 300, each card 104 can be the same as, or different from, another card 104. That is, the stacked arrangement of cards 104 may be the same cards or a mixed group of cards 104. Preferably, the securing member 300 contacts the edge of the card 104 opposite the edge electrically coupled to the socket to apply pressure efficiently.

Preferably, the securing member 300 comprises a fastening mechanism 308 adapted to prevent the securing member 300 from sliding when engaged. As pictured, the fastening mechanism 308 is a latch 308 adapted to engage the chassis 102 at an indentation in the chassis 102; however, all fastening mechanisms are within the scope of the disclosure. The tip 322 of the latch 308 preferably comprises a gripping material such that the securing member 300 will only decouple from the chassis 102 when desired. When the fastening mechanism 308 is engaged, each card 104 should contact different elastic portions 304 of the securing member 300 such that the securing member 300 secures the cards in their respective sockets. Also, when the fastening mechanism 308 is engaged, the securing member 300 should not slide along the rail 200. However, when the fastening mechanism 308 is not engaged, the securing member 300 should be free to slide along the rail 200 and even decouple from the rail 200.

FIGS. 5A and 5B illustrate repositioning the securing member 300 due to a shorter second card 504. As pictured in FIG. 5A, the securing member 300 is slidably coupled to the rail 200 and fastened to the computer chassis 102. The securing member 300 contacts a first card 502 at a first location 506. However, the securing member 300 does not contact a newly added second card 504 because the second card 504 has different dimensions from the first card 502. Specifically, the second card 504 has a shorter edge. Moving from FIG. 5A to FIG. 5B, the securing member 300 is preferably unfastened from the chassis 102 and repositioned in the direction indicated by arrow 550 to contact the first card 502 in another location 508 such that the securing member 300 does contact the second card at location 510. Hence, both cards 502, 504 are secured in their respective sockets via different elastic portions 304 once the securing member is refastened to the chassis 102 in the new position. As such, the securing member 300 is adapted to secure multiple cards in multiple sockets respectively by contacting the edges of the multiple cards even if the cards do not share the same dimensions.

The above disclosure is meant to be illustrative of the principles and various embodiment of the present invention. Numerous variations and modifications will become apparent to those skilled in the art once the above disclosure is fully appreciated. It is intended that the following claims be interpreted to embrace all variations and modifications.

I claim:

1. An apparatus, comprising:
a rail; and
a securing member slidably coupled to the rail, the securing member adapted to secure a card in a socket by contacting an edge of the card.

2. The apparatus of claim 1, wherein the securing member is adapted to secure the card by contacting any point along the edge of the card.

3. The apparatus of claim 1, wherein the securing member comprises an elastic portion at a point of contact with the edge of the card.

4. The apparatus of claim 1, wherein the rail comprises a groove in which a portion of the securing member slides.

5. The apparatus of claim 1, wherein the securing member comprises a hinge.

6. The apparatus of claim 5, wherein
the hinge couples a first portion of the securing member to a second portion of the securing member; and
a segment of the first portion of the securing member is adapted to slide in a groove in the rail.

7. The apparatus of claim 6, wherein the first portion of the securing member comprises wheels.

8. The apparatus of claim 1, wherein the securing member is adapted to secure multiple cards in multiple sockets respectively by contacting edges of the multiple cards, each of the multiple cards having non-identical dimensions.

9. The apparatus of claim 1, wherein the rail is coupled to a computer chassis.

10. The apparatus of claim 1, wherein the securing member comprises a fastening mechanism, the fastening mechanism adapted to prevent the securing member from sliding when engaged.

11. The apparatus of claim 10, wherein the fastening member engages with a computer chassis to prevent the securing member from sliding.

12. The apparatus of claim 1, wherein the apparatus comprises a computer.

13. The apparatus of claim 1, wherein the card is a peripheral component interconnect (“PCI”) card.

14. An apparatus, comprising:
a securing means for securing a card in a socket by contacting an edge of the card; and
an anchoring means for anchoring the securing means;
wherein the securing means is slidably coupled to the anchoring means.

15. The apparatus of claim 14, wherein the securing means further comprises a cushioning means for cushioning a point of contact between the securing means and the edge of the card.

16. The apparatus of claim 14, wherein the securing means comprises a moving means for moving along the anchoring means.

17. The apparatus of claim 14, further comprising a preventing means for preventing the securing means from sliding when engaged.

18. The apparatus of claim 15, wherein the card is a peripheral component interconnect (“PCI”) card.

19. An apparatus, comprising:
a rail; and
a securing member slidably coupled to the rail, the securing member adapted to secure a card in a socket by contacting an edge of the card;
wherein the securing member comprises:
an elastic portion at a point of contact with the edge of the card;
a fastening mechanism, the fastening mechanism adapted to prevent the securing member from sliding when engaged.

20. The apparatus of claim 19, wherein the card is a peripheral component interconnect (“PCI”) card.
